(19) United States
(12) Patent Application Publication
(10) Pub. No.: US 2023/0128273 A1
(43) Pub. Date: Apr. 27, 2023

(54) THIN FILM TRANSISTOR SUBSTRATE AND DISPLAY MODULE COMPRISING SAME

(71) Applicant: SAMSUNG ELECTRONICS CO., LTD., Suwon-si (KR)

(72) Inventors: Donggun OH, Suwon-si (KR); Jinho Kim, Suwon-si (KR); Kisun Kang, Suwon-si (KR)

(73) Assignee: SAMSUNG ELECTRONICS CO., LTD., Suwon-si (KR)

(21) Appl. No.: 18/086,225

(22) Filed: Dec. 21, 2022

Related U.S. Application Data
(63) Continuation of application No. PCT/KR2021/007112, filed on Jun. 8, 2021.

(30) Foreign Application Priority Data
Jun. 25, 2020 (KR) 10-2020-0078041
Feb. 9, 2021 (KR) 10-2021-0018548

(51) Int. Cl. H01L 33/62; H01L 25/075; H01L 33/38

(52) U.S. Cl. CPC H01L 33/62; H01L 25/0753; H01L 33/38

(57) ABSTRACT

A thin film transistor substrate and a display module comprising same are provided. The disclosed thin film transistor (TFT) substrate includes: a substrate; first and second inorganic insulating layers which are successively laminated on the substrate; a first metal layer which is formed between the first and second inorganic insulating layers; a second metal layer which is formed on the second inorganic insulating layer; first, second, and third organic insulating layers which are successively laminated on the second inorganic insulating layer; a third metal layer which is formed between the first and second organic insulating layers; and a fourth metal layer which is formed between the second and third organic insulating layers, wherein at least one of the second and third organic insulating layers is configured to absorb light..

### CROSS-REFERENCE TO RELATED APPLICATIONS

This application is a by-pass continuation application of International Application No. PCT/KR2021/007112, filed on Jun. 8, 2021, which based on and claims priority to Korean Patent Application No. 10-2020-0078041, filed on Jun. 25, 2020, and Korean Patent Application No. 10-2021-0018548, filed on Feb. 9, 2021,in the Korean Intellectual Property Office, the disclosures of which are incorporated by reference herein in their entireties.

### BACKGROUND

### 1. Field

The disclosure relates to a thin film transistor (TFT) substrate and a display module including the same, and more particularly, to a TFT substrate in which visible spots on a screen as light emitted from an inorganic self-luminous device and external light are reflected on a metal wiring disposed in the substrate is minimized, and a display module including the same.

### 2. Description of Related Art

Display panels are operated in units of pixels or sub-pixels including a plurality of micro light emitting diodes (LEDs) to represent various colors. The operation of each pixel or sub-pixel is controlled by a TFT.

Display panels use a thin film transistor substrate on which a TFT circuit is formed to drive a plurality of micro LEDs.

In case of a display panel to which micro LEDs are applied, more metal wirings are required than liquid crystal displays (LCDs) and organic light emitting diodes (OLEDs) to display, while maintaining uniformity without voltage drop (IR drop or ohmic drop) at high brightness. However, an increase in the metal wirings has a problem in that spots are visible on a screen of the display panel due to internal reflection by light emitted from the micro LED, which is a self-luminous device for displaying an image, and external reflection by external light.

### SUMMARY

Provided are a TFT substrate in which spots visible as light of an inorganic self-luminous device for displaying an image and external light are reflected by metal wirings are minimized, and a display module including the same.

According to an aspect of the disclosure, a thin film transistor (TFT) substrate includes: a substrate; a first inorganic insulating layer provided on the substrate; a second inorganic insulating layer provided on the first inorganic insulating layer; a first metal layer provided between the first inorganic insulating layer and the second inorganic insulating layer; a second metal layer provided on the second inorganic insulating layer; a first organic insulating layer provided on the second inorganic insulating layer; a second organic insulating layer provided on the first organic insulating layer; a third organic insulating layer provided on the second organic insulating layer; a third metal layer formed between the first organic insulating layer and the second organic insulating layer; and a fourth metal layer provided between the second organic insulating layer and the third organic insulating layer, wherein at least one of the second organic insulating layer and the third organic insulating layer is configured to absorb light.

Each of the second organic insulating layer and the third organic insulating layer may have a black-based color that absorbs light.

The third organic insulating layer may include carbon.

The second organic insulating layer may include carbon.

The substrate may be a glass substrate, a synthetic resin-based substrate having a flexible material, or a ceramic substrate.

The third organic insulating layer may have a rough surface formed by a plasma surface treatment.

According to an aspect of the disclosure, a display module includes: a substrate; and a plurality of self-luminous devices provided on the substrate; wherein the substrate includes: a glass substrate, a first organic insulating layer, a second organic insulating layer, and a third organic insulating layer sequentially stacked on the glass substrate, and a metal layer provided between the second organic insulating layer and the third organic insulating layer, wherein at least one of the second organic insulating layer and the third organic insulating layer is configured to absorb light.

Each of the second organic insulating layer and the third organic insulating layer may have a black-based color.

The third organic insulating layer may include carbon.

The second organic insulating layer may include carbon.

Each of the second organic insulating layer and the third organic insulating layer may be configured to absorb light.

The third organic insulating layer may have a rough surface formed by a plasma surface treatment.

The metal layer may have a first protrusion that protrudes further toward the third organic insulating layer than an interface between the second organic insulating layer and the third organic insulating layer, and the third organic insulating layer may have a second protrusion that protrudes further than a surface of the third organic insulating layer due to the first protrusion.

The substrate may be provided with a plurality of thin film transistor (TFT) electrode pads to which a chip electrode pad of each self-luminous device is connected, and a length of each TFT electrode pad may be longer than a length of each self-luminous device.

The substrate may be provided with a plurality of thin film transistor (TFT) electrode pads to which a chip electrode pad of each self-luminous device is connected, and the TFT electrode pad may include a mounting area and a redundancy area extending from the mounting area to allow the self-luminous device for repair to be mounted thereon.

### DESCRIPTION OF THE DRAWINGS

The above and other aspects, features, and advantages of certain embodiments of the present disclosure will be more apparent from the following description taken in conjunction with the accompanying drawings, in which:

FIG. 1 is a plan view schematically illustrating a display module according to an embodiment of the disclosure;

FIG. 2 is an enlarged view schematically illustrating one pixel area illustrated in FIG. 1; and

FIG. 3 is an enlarged cross-sectional view schematically illustrating a portion of a thin film transistor substrate of a display module according to an embodiment of the disclosure.

### DETAILED DESCRIPTION

Hereinafter, various embodiments will be described in detail with reference to the accompanying drawings. The embodiments described herein may be variously modified. Specific embodiments may be illustrated in the drawings and described in detail in the detailed description. It should be understood, however, that the specific embodiments disclosed in the accompanying drawings are intended only to facilitate understanding of various embodiments. Therefore, the technical idea is not limited by the specific embodiments disclosed in the accompanying drawings but includes all equivalents or alternatives falling within the spirit and scope of the disclosure.

Terms including ordinals, such as first, second, etc., may be used to describe various elements but such elements are not limited to the above terms. The above terms are used only for the purpose of distinguishing one component from another.

In this specification, the terms “comprise,” “include,” or “have” and the like, are intended to specify the presence of stated features, integers, steps, operations, elements, parts, or combinations thereof, but do not preclude the presence or addition of one or more other features, integers, steps, operations, elements, components, or combinations thereof. It is to be understood that when an element is referred to as being “connected” to another element, it may be directly on or directly connected to the other element or layer, or intervening elements or layers may be present. When an element is referred to as being “directly connected” to another element, it should be understood that there are no other elements in between.

In the disclosure, the expression ‘the same’ means not only to completely match, but also include a degree of difference in consideration of a processing error range.

In the following description, when the detailed description of the relevant known function or configuration is determined to unnecessarily obscure the important point of the disclosure, the detailed description will be omitted.

In the disclosure, a display module may be a display panel including an inorganic light emitting device (e.g., micro LED or µLED) for displaying an image. The display module is one of the flat panel display panels, equipped with multiple inorganic light emitting diodes (inorganic LEDs) of 100 micrometers or less mounted thereon, providing better contrast, response time and energy efficiency compared with liquid crystal display (LCD) panels that require a backlight.

In the disclosure, both an organic LED (OLED) and the micro LED that is an inorganic light emitting device have good energy efficiency, but the micro LED has better brightness and luminous efficiency and longer lifespan than the OLED. The micro LED may be a semiconductor chip that may emit light by itself when power is supplied thereof. The micro LED has fast response speed, low power, and high luminance. For example, the micro LED has a higher efficiency of converting electricity into photons than existing LCDs or OLEDs. In other words, the micro LED has a higher “brightness per watt” compared to the existing LCD or OLED displays. Accordingly, the micro LED may produce the same brightness with about half the energy compared to existing LEDs (width, length, and height each exceed 100 µm) or OLEDs. In addition, the micro LED may realize high resolution, excellent color, contrast, and brightness, thereby representing a wide range of colors accurately and realizing a clear screen even in bright sunlight. In addition, the micro LED is strong against a burn-in phenomenon and has low heat generation, thereby guaranteeing long lifespan without a deformation. The micro LED may have a flip chip structure in which anode and cathode electrodes are formed on the same first surface and a light emitting surface is formed on a second surface opposite to the first surface on which the electrodes are formed.

In the disclosure, a thin film transistor (TFT) layer including a TFT circuit is disposed on a front surface of a substrate, and a power supply circuit supplying power to the TFT circuit, a data driver, a gate driver, and a timing controller controlling each driver may be arranged on a rear surface of the substrate. A plurality of pixels arranged in the TFT layer may be driven by the TFT circuit.

In the disclosure, the substrate may be a glass substrate, a synthetic resin-based substrate having a flexible material (e.g., polyimide (PI), polyethylene terephthalate (PET), polyethersulfone (PES), polyethylene naphthalate (PEN), polycarbonate (PC), etc., or a ceramic substrate.

In the disclosure, a TFT layer including a TFT circuit formed thereon may be disposed on the front surface of the substrate, and no circuit may be disposed on the rear surface of the substrate. The TFT layer may be integrally formed on the substrate or may be manufactured in the form of a separate film and attached to one surface of the glass substrate.

In the disclosure, the front surface of the substrate may be divided into an active area and a dummy area. The active area may correspond to a region occupied by the TFT layer on the front surface of the substrate, and the dummy area may be a region excluding the region occupied by the TFT layer on the front surface of the substrate.

In the disclosure, an edge area of the substrate may be the outermost region of the glass substrate. Also, the edge area of the substrate may be a remaining region except for a region in which circuits of the substrate are formed. Also, the edge area of the substrate may include a portion of the front surface of the substrate adjacent to a side surface of the substrate and a portion of the rear surface of the substrate adjacent to the side surface of the substrate. The substrate may be formed to be a quadrangle. For example, the substrate may be formed to have a rectangular shape or a square shape. The edge area of the substrate may include at least one of four sides of the glass substrate.

In the disclosure, the TFT constituting the TFT layer (or backplane) is not limited to a specific structure or type, For example, the TFT cited in the disclosure may also be implemented as an oxide TFT, Si (poly silicon, a-silicon) TFT, organic TFT, graphene TFT, etc., in addition to a low-temperature polycrystalline silicon TFT (LTPS TFT), and only P-type (or N-type) MOSFETs may be generated in an Si wafer CMOS process and applied.

In the disclosure, the substrate included in the display module is not limited to the TFT substrate. For example, the display module may be a substrate without a TFT layer on which a TFT circuit is formed. In this case, the display module may include a substrate on which only wirings are patterned, while a micro IC is separately mounted.

In the disclosure, a pixel driving method of the display module may be an active matrix (AM) driving method or a passive matrix (PM) driving method. The display module may include a pattern of wirings to which each micro LED is electrically connected according to the AM driving method or the PM driving method.

In the disclosure, the display module may include a glass substrate on which a plurality of LEDs are mounted and a side wiring is formed. Such a display module may be individually installed and applied to wearable devices, portable devices, handheld devices, electronic products requiring various displays, or electric devices, and may be applied to display devices, such as monitors for personal computers (PCs), high-resolution TVs, such as signages (or digital signages), electronic displays, and the like, through a plurality of assembly arrangements as a matrix type.

Hereinafter, a display module according to an embodiment of the disclosure will be described with reference to the drawings.

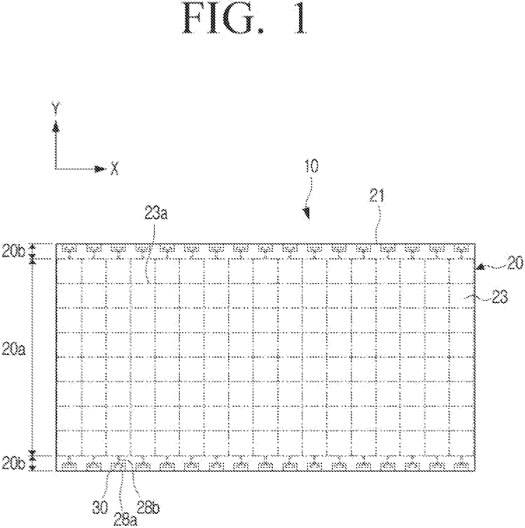

FIG. 1 is a plan view schematically illustrating a display module according to an embodiment of the disclosure.

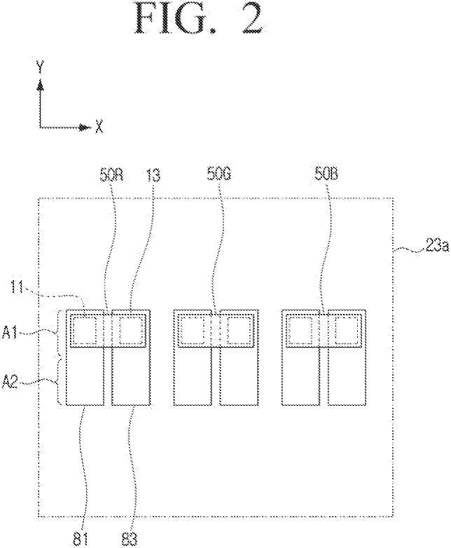

Referring to FIGS. 1 and 2, a display module 10 may include a plurality of micro LEDs 50R, 50G, and 50B for displaying an image, arranged on a TFT substrate 20. The plurality of micro LEDs 50R, 50G, and 50B may be sub-pixels constituting a single pixel. In the disclosure, one ‘micro LED’ and one ‘sub-pixel’ may be used interchangeably as the same meaning.

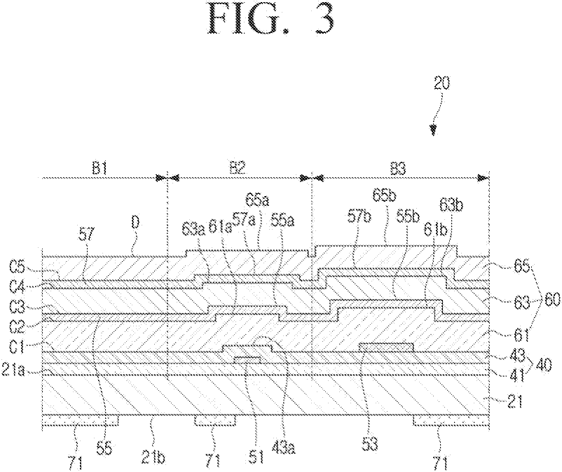

The TFT substrate 20 may include a glass substrate 21, a TFT layer 23 including a TFT circuit on a front surface of the glass substrate 21, a TFT circuit of the TFT layer 23 and circuits disposed on a rear surface 21b of the glass substrate 21, and a plurality of side wirings 30 electrically connecting a plurality of metal wirings 71 (refer to FIG. 3).

In an embodiment, as an alternative to the glass substrate 21, a synthetic resin series having a flexible material (e.g., PI, PET, PES, PEN, PC, etc.) or a ceramic substrate may be used.

The TFT substrate 20 includes an active area 20a that displays an image and a dummy area 20b that cannot display an image on a front surface thereof.

In the active area 20a, a pixel area 23a in which a plurality of sub-pixels and corresponding TFTs are disposed may be arranged in a matrix form.

The dummy area 20b may be included in an edge area of the glass substrate 21, and a plurality of connection pads 28a may be arranged at regular intervals. The plurality of connection pads 28a may be electrically connected to the sub-pixels, respectively, through a wiring 28b.

The number of connection pads 28a formed in the dummy area 20b may vary depending on the number of pixels implemented on the glass substrate and may vary depending on a driving method of the TFT circuit disposed in the active area 20a. For example, as for the TFT circuit disposed in the active area 20a, the AM driving method in which each pixel is individually driven may require more wirings and connection pads, compared with the PM driving method in which a plurality of pixels are driven in a horizontal line and a vertical line.

In the TFT substrate 20 of the display module 10, the side wiring 30 may not be formed on the side of the glass substrate 21, but may be formed through a via hole wiring formed through a through glass via (TGV) process. The via hole wiring may electrically connect the wiring 28b formed on the front surface of the glass substrate 21 to the wiring 71 (refer to FIG. 3) formed on the rear surface of the glass substrate 21. In this case, the plurality of connection pads 28a connected to the plurality of side wirings 30 may be omitted.

The plurality of micro LEDs 50R, 50G, and 50B may be formed of an inorganic light emitting material and may be semiconductor chips capable of emitting light by itself when power is supplied thereto. For example, the plurality of micro LEDs 50R, 50G, and 50B may have a flip chip structure in which anode and cathode electrodes are formed on the same surface and a light emitting surface is formed on a surface opposite to the electrodes.

The plurality of micro LEDs 50R, 50G, and 50B may have a predetermined thickness and may be formed to have a square having the same width and length or have a rectangle having different widths and lengths. Such a micro LED may implement real high dynamic range (HDR), improve luminance and black expressiveness, and provide a high contrast ratio, compared to OLEDs. A size of the micro LED may be 100 µm or less, or preferably 30 µm or less.

In the display module 10, a black matrix partitioning the plurality of micro LEDs 50R, 50G, and 50B may be formed on the TFT layer 23 in a substantially lattice shape. In this case, the display module 10 may include a transparent cover layer covering the plurality of micro LEDs 50R, 50G, and 50B and the black matrix to protect the plurality of micro LEDs 50R, 50G, and 50 and the black matrix together. A touch screen panel may be stacked and disposed on an outer surface of the transparent cover layer.

FIG. 2 is an enlarged view schematically illustrating one pixel area illustrated in FIG. 1.

Referring to FIG. 2, red, green, and blue micro LEDs 50R, 50G, and 50B that are sub-pixels may be disposed in one pixel area 23a. In the red micro LED 50R, a pair of chip electrode pads 11 and 13 may be electrically connected to the TFT electrode pads 81 and 83 arranged on the TFT substrate 20. Also, in the green and blue micro LEDs 50G and 50B, a pair of chip electrode pads are electrically connected to the corresponding TFT electrode pads, respectively.

A length (length in a Y-axis direction) of the TFT electrode pads 81 and 83 may be longer than a length (length in an X-axis direction) of the micro LED. The TFT electrode pads 81 and 83 may include a mounting area A1 and a redundancy area A2 extending from the mounting area A1.

If the micro LEDs 50R, 50G, and 50B connected to the mounting area A1 of the TFT electrode pads 81 and 83 are defective, there is no need to remove the micro LED in the mounting area A1 to repair it, and a micro LED for repairing may be mounted in the redundancy area A2. Accordingly, a repair operation may be performed quickly without a process of removing the defective micro LED from the TFT electrode pads 81 and 83.

FIG. 3 is an enlarged cross-sectional view schematically illustrating a portion of a TFT substrate of a display module according to an embodiment of the disclosure.

Referring to FIG. 3, in the TFT substrate 20, a plurality of inorganic insulating layers 40 and a plurality of organic insulating layers 60 may be sequentially stacked on the front surface of the glass substrate 21. In this case, the inorganic insulating layer 40 and the organic insulating layer 60 may be stacked in two or more layers, respectively. For example, the plurality of inorganic insulating layers 40 may comprise first and second inorganic insulating layers 41 and 43, and the plurality of organic insulating layers 60 may comprise first, second, and third inorganic insulating layers 61, 63, and 65.

In addition, in the TFT substrate 20, first, second, third, and fourth metal layers 51, 53, 55, and 57 may be disposed at different positions between the plurality of inorganic insulating layers 40 and between the plurality of organic insulating layers 60.

The plurality of inorganic insulating layers 40 and the plurality of organic insulating layers 60 are formed as thin films by a physical vapor deposition (PVD) method, such as thermal evaporation, e-beam evaporation, or sputtering, a chemical vapor deposition (CVD) method, such as plasma enhanced CVD (PECVD) or a high density plasma CVD (HDPCVD), or atomic layer deposition (ALD), etc.

The first inorganic insulating layer 41 may be a gate insulating layer deposited on a front surface 21a of the glass substrate 21. In this case, the first inorganic insulating layer 41 may be formed of an inorganic material, such as SiO₂, SiNx, SiON, or Al₂O₃.

A first metal layer 51 corresponding to a gate electrode may be formed on the first inorganic insulating layer 41. The first metal layer 51 may be a metal wiring that does not correspond to a gate electrode.

The second inorganic insulating layer 43 may be deposited on the first inorganic insulating layer 41 and the first metal layer 51 to cover both the first inorganic insulating layer 41 and the first metal layer 51. The second inorganic insulating layer 43 may have an approximately similar thickness as a whole.

A portion of the second inorganic insulating layer 43 covering the first metal layer 51 may form a first protrusion 43a protruding substantially corresponding to a thickness of the first metal layer 51.

The first protrusion 43a may protrude further toward the first organic insulating layer 61 than an interface C1 between the second inorganic insulating layer 43 and the first organic insulating layer 61. The first protrusion 43a causes a portion of the third and fourth metal layers 55 and 57 formed between the plurality of organic insulating layers 60 to protrude.

A second metal layer 53 corresponding to a source/drain electrode may be formed on the second inorganic insulating layer 43. The second metal layer 53 may be a metal wiring that does not correspond to a source/drain electrode.

The first organic insulating layer 61 may be deposited on the second inorganic insulating layer 43 and the second metal layer 53 to cover the second inorganic insulating layer 43 and the second metal layer 53 together. The first organic insulating layer 61 may have an approximately similar thickness as a whole.

A portion of the first organic insulating layer 61 covering the second metal layer 53 may form a second protrusion 61a protruding by an amount corresponding to the thickness of the first protrusion 43a, and another portion of the first organic insulating layer 61 may form a third protrusion 61b protruding by an amount corresponding to the thickness of the second metal layer 53. The second and third protrusions 61a and 61b may protrude further toward the second organic insulating layer 63 than an interface C2 between the first organic insulating layer 61 and the third metal layer 55.

The third metal layer 55 may be deposited on the first organic insulating layer 61 and may have an approximately similar thickness as a whole. A portion of the third metal layer 55 may form a fourth protrusion 55a protruding toward the fourth metal layer 57 by the second protrusion 61a of the first organic insulating layer 61, and another portion of the third metal layer 55 may form a fifth protrusion 55b protruding toward the fourth metal layer 57 by the third protrusion 61b of the first organic insulating layer 61. The fourth and fifth protrusions 55a and 55b may protrude more toward the fourth metal layer 57 than an interface C3 between the third metal layer 55 and the second organic insulating layer 63.

The second organic insulating layer 63 may be deposited on the third metal layer 55 and may have an approximately similar thickness as a whole. A portion of the second organic insulating layer 63 may form a sixth protrusion 63a protruding toward the third organic insulating layer 65 by the fourth protrusion 55a of the third metal layer 55, and another portion of the second organic insulating layer 63 may form a seventh protrusion 63b protruding toward the third metal layer 55 by the fifth protrusion 55b of the second metal layer 55. The sixth and seventh protrusions 63a and 63b may protrude further toward the fourth metal layer 57 than an interface C4 between the third metal layer 55 and the second organic insulating layer 63.

The second organic insulating layer 63 may have a black-based color having excellent light absorption. In this case, the second organic insulating layer 63 may comprise a material having a black-based color, for example, carbon. The amount of carbon included in the second organic insulating layer 63 may be as much as to sufficiently maintain non-conductivity of the second organic insulating layer 63.

The fourth and fifth protrusions 55a and 55b of the aforementioned third metal layer 55 are formed in an approximately concave-convex shape, and thus serve as a convex lens reflecting light emitted from the micro LED, which is a self-luminous device, and external light to cause spots on a screen of the display module 10 to be visible.

According to an embodiment, because the second organic insulating layer 63 has a black-based color with excellent light absorption, the second organic insulating layer 63 may effectively absorb light emitted from the micro LED and external light, thereby fundamentally blocking light emitted from the micro LED and external light reflected from the fourth and fifth protrusions 55a and 55b of the third metal layer 55. Accordingly, it is possible to prevent spots from being visible on the screen of the display module 10.

The fourth metal layer 57 may be deposited on the second organic insulating layer 63 and may have an approximately similar thickness as a whole. A portion of the fourth metal layer 57 may form an eighth protrusion 57a protruding toward the third organic insulating layer 65 by the sixth protrusion 63a of the second organic insulating layer 63, and another portion of the fourth metal layer 57 may form a ninth protrusion 57b protruding toward the third organic insulating layer 65 by the seventh protrusion 63b of the second organic insulating layer 63. The eighth and ninth protrusions 57a and 57b may protrude further toward the third insulating organic layer 65 than an interface C5 between the fourth metal layer 57 and the third organic insulating layer 65.

The third organic insulating layer 65 may be deposited on the fourth metal layer 57 and may have an approximately similar thickness as a whole. A portion of the second organic insulating layer 63 may form a tenth protrusion 65a protruding by the eighth protrusion 57a of the fourth metal layer 57, and another portion of the third organic insulating layer 65 may form an eleventh protrusion 65b protruding by the ninth protrusion 57b of the fourth metal layer 57. The tenth and eleventh protrusions 65a and 65b may protrude further than a surface D of the third organic insulating layer 63.

Like the second organic insulating layer 63, the third organic insulating layer 65 may have a black-based color having excellent light absorption. In this case, the third organic insulating layer 65 may comprise a material having a black-based color, for example, carbon. The amount of carbon included in the third organic insulating layer 65 may be as much as to sufficiently maintain non-conductivity of the third organic insulating layer 65.

As the eighth and ninth protrusions 57a and 57b of the fourth metal layer 57 described above are formed to have a substantially concave-convex shape, the eighth and ninth protrusions 57a and 57b may serve as a convex lens reflecting light emitted from the micro LED, which is a self-luminous device, and external light, like the fourth and fifth protrusions 55a and 55b of the third metal layer 55, and thus, the eighth and ninth protrusions 57a and 57b may cause spots to be visible on the screen of the display module 10.

The eighth protrusion 57a of the fourth metal layer 57 may be a horizontal line region B2 that may be visible as a horizontal wiring (the X-axis direction in FIG. 1) of the TFT substrate 20 when light is reflected, and the ninth protrusion 57b of the fourth metal layer 57 may be a vertical line region B3 that may be visible as a vertical wiring (the Y-axis direction of FIG. 1) of the TFT substrate 20 when light is reflected. In FIG. 3, reference numeral B1 corresponds to a normal region in which a metal wiring is not visible.

According to an embodiment, because the third organic insulating layer 65 has a black-based color with excellent light absorption, the third organic insulating layer 65 effectively absorbs light emitted from the micro LED and external light, so that light emitted from the micro LED and external light may be fundamentally prevented from being reflected to the eighth and ninth protrusions 57a and 57b of the fourth metal layer 57.

Accordingly, according to an embodiment, it is possible to prevent the horizontal wiring and the vertical wiring of the TFT substrate from being visible, which means that spots are not visible on the screen of the display module 10.

In an embodiment, surface roughness of the third organic insulating layer 65 may be increased through an ashing process (a plasma surface treatment) to minimize reflectance of the third organic insulating layer 65.

As described above, according to an embodiment, by disposing the second and third organic insulating layers 63 and 65 having a black-based color below and above the fourth metal layer 57 in the TFT substrate 20 located to be closest to the micro LED mounted on the front surface of the TFT substrate 20, light emitted from the micro LED and external light may be fundamentally prevented from being reflected to the fourth metal layer 57.

Various embodiments of the disclosure have been individually described but the embodiments may not necessarily be implemented alone and components and operations of the respective embodiments may be combined with at least any other embodiment so as to be implemented.

Although the embodiments have been illustrated and described hereinabove, the disclosure is not limited to the above-mentioned specific embodiments, but may be variously modified by those skilled in the art without departing from the scope and spirit of the disclosure as disclosed in the accompanying claims. These modifications should also be understood to fall within the scope of the disclosure.

What is claimed is:

1. A thin film transistor (TFT) substrate comprising:
a substrate;
a first inorganic insulating layer provided on the substrate;
a second inorganic insulating layer provided on the first inorganic insulating layer;
a first metal layer provided between the first inorganic insulating layer and the second inorganic insulating layer;
a second metal layer provided on the second inorganic insulating layer;
a first organic insulating layer provided on the second inorganic insulating layer;
a second organic insulating layer provided on the first organic insulating layer;
a third organic insulating layer provided on the second organic insulating layer;
a third metal layer formed between the first organic insulating layer and the second organic insulating layer; and
a fourth metal layer provided between the second organic insulating layer and the third organic insulating layer,
wherein at least one of the second organic insulating layer and the third organic insulating layer is configured to absorb light.

2. The TFT substrate of claim 1, wherein each of the second organic insulating layer and the third organic insulating layer has a black-based color that absorbs light.

3. The TFT substrate of claim 1, wherein the third organic insulating layer comprises carbon.

4. The TFT substrate of claim 3, wherein the second organic insulating layer comprises carbon.

5. The TFT substrate of claim 1, wherein the substrate is a glass substrate, a synthetic resin-based substrate having a flexible material, or a ceramic substrate.

6. The TFT substrate of claim 1, wherein the third organic insulating layer has a rough surface formed by a plasma surface treatment.

7. A display module comprising:
a substrate; and
a plurality of self-luminous devices provided on the substrate;
wherein the substrate comprises:
a glass substrate, a first organic insulating layer, a second organic insulating layer, and a third organic insulating layer sequentially stacked on the glass substrate, and
a metal layer provided between the second organic insulating layer and the third organic insulating layer,
wherein at least one of the second organic insulating layer and the third organic insulating layer is configured to absorb light.

8. The display module of claim 7, wherein each of the second organic insulating layer and the third organic insulating layer has a black-based color.

9. The display module of claim 7, wherein the third organic insulating layer comprises carbon.

10. The display module of claim 9, wherein the second organic insulating layer comprises carbon.

11. The display module of claim 7, wherein each of the second organic insulating layer and the third organic insulating layer is configured to absorb light.

12. The display module of claim 7, wherein the third organic insulating layer has a rough surface formed by a plasma surface treatment.

13. The display module of claim 7, wherein the metal layer has a first protrusion that protrudes further toward the third organic insulating layer than an interface between the second organic insulating layer and the third organic insulating layer, and
the third organic insulating layer has a second protrusion that protrudes further than a surface of the third organic insulating layer due to the first protrusion.

14. The display module of claim 7, wherein the substrate is provided with a plurality of thin film transistor (TFT) electrode pads to which a chip electrode pad of each self-luminous device is connected, and
a length of each TFT electrode pad is longer than a length of each self-luminous device.

15. The display module of claim 7, wherein the substrate is provided with a plurality of thin film transistor (TFT) electrode pads to which a chip electrode pad of each self-luminous device is connected, and
the TFT electrode pad comprises a mounting area and a redundancy area extending from the mounting area to allow the self-luminous device for repair to be mounted thereon.
